(19) United States
(12) Patent Application Publication
(10) Pub. No.: US 2025/0220859 A1
(43) Pub. Date: Jul. 3, 2025

(54) Heat Sink

(71) Applicant: Telefonaktiebolaget LM Ericsson (publ), Stockholm (SE)

(72) Inventors: Stevin van Wyk, Täby (SE); Georg Hellström, Stockholm (SE)

(21) Appl. No.: 18/841,859

(22) PCT Filed: Feb. 24, 2023
(86) PCT No.: PCT/EP2023/054738

§ 371 Date: Aug. 27, 2024

Related U.S. Application Data
(60) Provisional application No. 63/268,620, filed on Feb. 28, 2022.

(51) Int. Cl. H05K 7/20

(52) U.S. Cl. CPC H05K 7/2039

(57) ABSTRACT

Embodiments herein relate to a heat sink for a radio unit. The heat sink (200) comprises a base (201) having a surface and a central longitudinal axis (A1), the surface comprising a first portion (202) and a second portion (204) disposed along the central longitudinal axis (A1) such that the first portion (202) is above the second portion (204). The heat sink further comprises a first plurality of projecting members (212) extending from the first portion (202) of the surface, wherein projecting members from the first plurality of projecting members (212) are elongated fully throughout the first portion (202) along the surface parallel to one another and to the central longitudinal axis (A1), and wherein the first plurality of projecting members (212) are uniformly spaced along the first portion (202). The heat sink comprises a second plurality of projecting members (214) extending from the second portion (204) of the surface, wherein at least parts or some projecting members of the second plurality of projecting members (214) are straightly elongated along the surface and arranged angled relative to the first plurality of projecting members (212).

### TECHNICAL FIELD

Embodiments herein relate to a heat sink, in particular to a heat sink for a radio unit such as a remote radio device.

### BACKGROUND

Proper operation of modern electronic equipment frequently requires ways to dissipate heat generated by electronic components of the equipment. Thermal management of electronic equipment thus becomes increasingly important. For example, a remote radio unit (RRU) has been widely used in the third-generation mobile communication technology to convert an optical signal into a radio frequency signal and perform signal amplification. RRUs, which may be positioned on cell towers, may, in operation, generate excessive quantities of heat and thus increasingly have thermal demands. Adequate cooling is required to maintain the reliability and functionality of the RRUs, and to increase their life.

A heat sink device, or a heat sink, is often used to dissipate heat in devices including electronic components, such as RRUs. A heat sink is typically a passive heat exchanger device that functions to regulate the temperature of an electronic and/or mechanical device, by absorbing and dispersing heat away from the device, to the surroundings. It transfers heat from a heat-generating component to air (or liquid coolant), allowing the heat to dissipate away from the device.

Although various configurations of heat sinks exist, there is still a need for a heat sink having a structure that efficient in heat dissipation and has other beneficial features.

### SUMMARY

As part of developing embodiments herein, one or more problems have been identified. In particular, electronic devices, e.g., processing units such as RRUs, are often hard pressed for size in general and have increasing thermal demands with time. At the same time, wind-driven acoustical noise, which may be generated by a heat sink coupled to the electronic device, also becomes an issue, due to, e.g., the effects of geometrical uniformity and size of existing heat sinks.

Conventional heat sinks typically have fins uniformly extending vertically along a base of the heat sink. The RRUs may be exposed to ambient wind travelling from different directions and at different speeds. When wind travels over an RRU or another object having a heat sink, cavities between cooling fins of the heat sink may cause a high pitched whistling noise. The frequency of the whistling noise is in a range that is audible to humans and animals, and creates an environmental and health concern. Moreover, remote radio products are directly exposed to the environment and therefore are affected by the atmospheric wind conditions that may lead to enhancement of certain acoustical frequencies that act as a disturbance to nearby settlements.

Various existing heat sinks are implemented so as to address either thermal performance or to reduce wind-driven acoustical noise (or address other concerns), but not both the thermal performance and noise generation.

Accordingly, embodiments of the present disclosure provide a heat sink that both improves thermal performance and provides damping/reduction of wind-driven acoustical noise, simultaneously. The heat sink provided herein is a unique natural convection heat sink structure/system, referred to as a hybrid heat sink or, interchangeably, a heat sink. The heat sink is optimized to operate with less noise that existing heat sinks, and may therefore be referred to as a silent hybrid heat sink.

In aspects of the present disclosure, a heat sink for a radio unit is provided that comprises a base having a surface and a central longitudinal axis, the surface comprising a first portion and a second portion disposed along the central longitudinal axis such that the first portion is above the second portion. The heat sink also comprises a first plurality of projecting members and a second plurality of projecting members, also referred to interchangeably as fins. Thus, the heat sink comprises the first plurality of projecting members extending from the first portion of the surface, wherein projecting members from the first plurality of projecting members are elongated fully throughout the first portion along the surface parallel to one another and to the central longitudinal axis, and wherein the first plurality of projecting members are uniformly spaced along the first portion. The heat sink further comprises the second plurality of projecting members extending from the second portion of the surface, wherein at least parts of or some projecting members of the second plurality of projecting members are straightly elongated along the surface and arranged angled relative to the first plurality of projecting members.

Thus, the heat sink is constructed of two main structural parts-a first portion having fins, or projecting members, like in a conventional heat sink, and a second portion having fins that are angled relative to the fins in the main portion, and may have channels extending therethrough. The fins in the second portion, in turn, may form two separate sets of fins, wherein fins in one set are inwardly and upwardly angled relative to fins in another set, i.e. inwardly and upwardly from the lower left corner of the second portion and inwardly and upwardly from the lower right corner of the second portion. The first portion, having fins as can be found in a conventional configuration, serves to create thermal cooling effect, and the second portion serves to cool and to reduce noise that may be generated by the heat sink in operation. Thus, the first and second portions function together to improve or maximize analog component performance, while decreasing the impact on the digital components by the analog components, offering the digital components more cooling potential. The provided implementation allows decreasing a heat sink weight, improves acoustic damping and facilitates fan flow.

The heat sink in accordance with embodiments of the present disclosure provides effective ways to both damp/break up wind-driven acoustical noise, improve thermal performance of the heat sink system without decreasing thermal potential of critical analog component cooling, and improve thermal performance of digital components of equipment that employs the heat sink. The heat sink has a robust flow path definition by having additional flow paths on side inlets of the heat sink structure, which reduce effects of possible flow obstruction. In addition, side access inlets for the heat sink further allow for enhanced cooling from outdoor wind fluctuations.

### BRIEF DESCRIPTION OF THE DRAWINGS

Embodiments will now be described in more detail in relation to the enclosed drawings, in which:

FIG. 1 is a diagram illustrating a view of a part of a conventional heat sink, showing schematically generation of a whistling noise due to wind.

FIG. 2 is a diagram illustrating a front view of a conventional heat sink.

FIG. 3 is a diagram illustrating a front view of a heat sink in accordance with embodiments of the present disclosure.

FIG. 4 are diagrams illustrating front views of a conventional heat sink (A); a heat sink having an alternative configuration (B); and a heat sink in accordance with embodiments of the present disclosure (C).

FIG. 5 is another diagram illustrating a front view of a heat sink in accordance with embodiments of the present disclosure.

FIG. 6 is a diagram illustrating a perspective side view of a heat sink in accordance with embodiments of the present disclosure.

FIG. 7 is a diagram illustrating a perspective view of a portion of a fin of the heat sink of FIG. 6, showing an angle of slanting of the portion of the fin due to a channel formed in the fin.

FIGS. 8A, 8B, and 8C are diagrams schematically illustrating shapes of channels extending through fins in the heat sink of FIG. 6, showing shapes of a top and bottom portions of a central channels (FIGS. 8A and 8B, respectively); and a shape of a side channel (FIG. 8C).

FIGS. 9A and 9B are diagrams schematically illustrating passage of wind through a conventional heat sink (FIG. 9A); and passage of wind through a heat sink in accordance with embodiments of the present disclosure (FIG. 9B).

FIG. 10 is a diagram illustrating a perspective side view of a heat sink in accordance with embodiments of the present disclosure.

FIG. 11 are diagrams illustrating perspective views of examples of heat sinks in panels A and B, in accordance with embodiments of the present disclosure.

FIG. 12 are diagrams illustrating other perspective views of the heat sinks of FIG. 11.

### DETAILED DESCRIPTION

Embodiments herein relate to a heat sink also referred to as a hybrid heat sink comprising a base having a first, top portion and a second, bottom portion, wherein a configuration of fins extending from the first portion is different from a configuration of fins extending along the second portion. These two structural parts of the heat sink allow both improving thermal performance of the heat sink, and damping/reduction of wind-driven acoustical noise that may be generated in the heat sink.

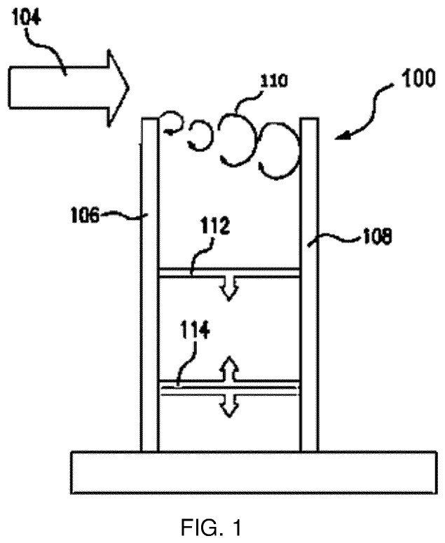

FIG. 1 shows schematically how a whistling noise can be generated in a heat sink 100, such as, e.g., in a conventional natural convection heat sink. The heat sink may be a passive heat sink in which buoyancy of hot air alone causes the airflow generated across the heat sink. As shown in FIG. 1, as wind 104 travels over projecting members or fins 106 and 108, such as cooling fins or fins for short, of the heat sink 100, the flow of wind 104 separates over the first and second fins 106 and 108, thereby causing vortices 110. When the vortices 110 hit the second fin 108, pressure fluctuation 112 may be created. If the pressure fluctuation 112 is caused by wind having certain wind speeds, the pressure fluctuation 112 may cause an acoustic feedback loop 114, thereby causing a whistling noise. This noise is audible to humans, animals, and bird, and may thus be a significant limiting factor in use of a heat sink such as the heat sink 100.

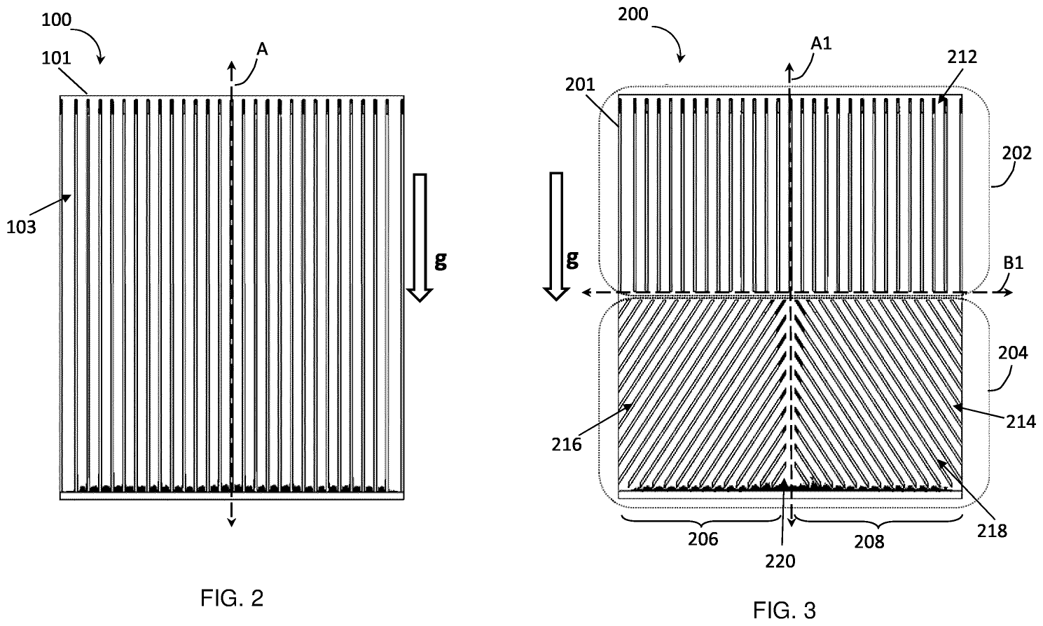

FIG. 2 illustrates a front view of the conventional heat sink 100, showing fins 103 extending on a surface of a base 101 of the heat sink 100 along a longitudinal axis A of the base 101. The heat sink 100 may be, e.g., a natural convection heat sink. In use, the heat sink 100 may be disposed vertically, and gravity g (the vertical force) is shown in FIG. 2 for illustration purposes. The fins 103 in the conventional heat sink 100 are uniformly spaced along the base 101 such that they form parallel rows of fins along the base 101.

In a conventional heat sink, such as, e.g., the heat sink 100 shown in FIG. 2, heat can spread with a high degree of efficiency from heat sources, e.g. high-density heat sources, via the standard straight fin structure. In this case, the high-density heat sources need to spread heat downwards to be cooled more efficiently. This, however, has a detrimental effect on the cooling potential of components disposed lower down along a path of heat distribution, such as, e.g., digital components. To improve the condition of the components lower down (e.g., digital components) and to still at least in part make use of the strengths of the conventional heat sink structure, a structure of a heat sink in accordance with embodiments of the present disclosure is provided herein. The heat sink comprises a base having a surface and a central longitudinal axis, the surface comprising a first portion and a second portion disposed along the central longitudinal axis such that the first portion is above the second portion. The heat sink further comprises a first plurality of projecting members extending from the first portion of the surface, wherein projecting members from the first plurality of projecting members are elongated fully throughout, or across, the first portion along the surface parallel to one another and to the central longitudinal axis, and wherein the first plurality of projecting members are uniformly spaced along the first portion. The heat sink also comprises a second plurality of projecting members extending from the second portion of the surface, wherein at least parts or some projecting members of the second plurality of projecting members are straightly elongated along the surface and arranged angled relative to the first plurality of projecting members.

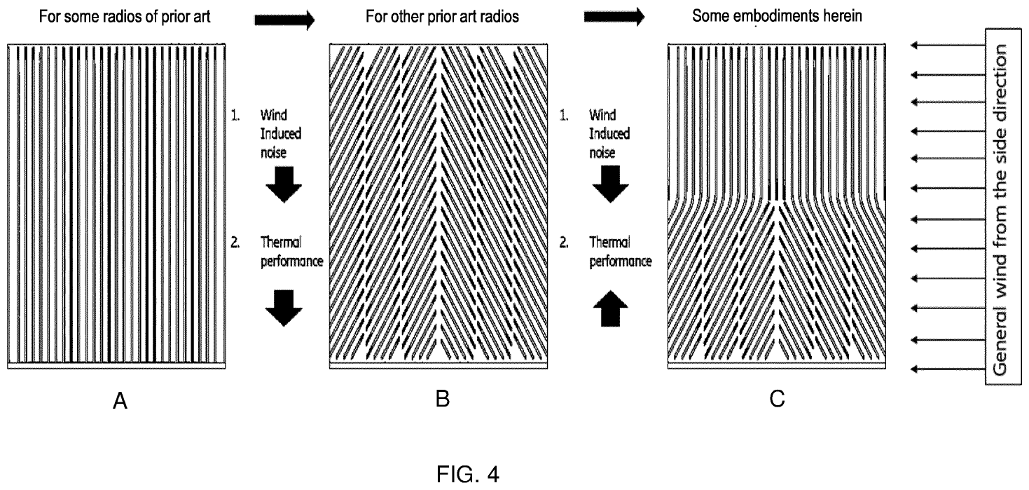

Thus, in the heat sink, constructed using a combination of fins in a conventional configuration and of angled fins, the angled fin structure, which may also be referred as a delta part or portion, is configured to change the heat transfer dynamics in both conduction and air flow paths. Less heat is thus transferred lower down in the heat sink, since more heat is conducted to the sides and dissipated with higher efficiency there due to improved inflow properties, such as cooler air and a collectively larger inlet area, bottom plus sides as inlets, instead of just bottom in the conventional heat sink. Because the heat is not conducted downwards as far as in existing systems, the lower part, generally, becomes cooler thereby reducing an impact from analog components on digital components. In embodiments herein, this lower part may be further enhanced by forming channels or cuts in fins of the lower part, as discussed in more detail below, with reference to FIGS. 4 (panel C), 5, 6, 9B, 10, 11, and 12.

FIG. 3 illustrates a front view of a hybrid heat sink 200 in accordance with embodiments of the present disclosure. The heat sink 200 comprises a base plate or base 201 having a surface and a central longitudinal axis A1. The surface, which is not separately labeled herein since it coincides with the base 201 in FIG. 3, comprises a first portion 202 and a second portion 204 disposed along the central longitudinal axis A1 such that the first portion 202 is above the second portion 204. The heat sink 200 also comprises a first plurality of projecting members or fins 212 and a second plurality of projecting members or fins 214. The first plurality of projecting members 212 and the second plurality of projecting members 214 may be plates, e.g., metal plates, having a uniform height throughout their length. The first plurality of projecting members 212 have the same length. Projecting members from the second plurality of projecting members 214 may have different lengths, as shown in FIG. 3.

The first portion 202 having the first plurality of projecting members 212 serves to create thermal cooling effect. The second portion 204 having the second plurality of projecting members 214 is configured to reduce or dampen acoustic noise that may be generated due to wind or other air movement.

The first plurality of projecting members 212 extend from the first portion 202 of the surface, wherein projecting members from the first plurality of projecting members 212 are elongated fully throughout, or across, the first portion 202 along the surface parallel to one another and to a longitudinal axis of the heat sink 200, such as the central longitudinal axis A1. The projecting members from the first plurality of projecting members 212 may be elongated along the surface substantially parallel to one another, i.e. they are parallel or parallel within an angle interval, such as within the angle interval due to manufacturing variations, tolerances, and imprecisions. The first plurality of projecting members 212 are substantially straight (i.e., straight or straight within an angle interval, such as within the interval due to manufacturing variations, tolerances, and imprecisions) and are uniformly spaced along the first portion 202. As shown in FIG. 3, the first plurality of projecting members 212 extend along the surface in parallel rows, in a manner that is the same or similar to the projecting members 103 of the conventional heat sink 100 of FIG. 2.

The second plurality of projecting members 214 extend from the second portion 204 of the surface. As shown in FIG. 3, at least parts or some projecting members of the second plurality of projecting members 214 are straightly elongated along the surface and arranged angled relative to the first plurality of projecting members 212. The projecting members from the second plurality of projecting members 214 may be in the form of elongated plates with their surfaces being perpendicular relative to the surface of the base 201, and the projecting members are positioned on the second portion 204 of the surface in an angled manner relative to the first plurality of projecting members 212.

There may be a space, e.g., along a transverse axis B1, between the second plurality of projecting members 214 and the first plurality of projecting members 202. The space may be infinitesimally small. Alternatively, some or all of the projecting members from the first plurality of projecting members 212 may each extend further, in an angled configuration, along the second portion 204 of the base 201, so as to also form projection members of the second plurality of projecting members 214.

In embodiments, the first plurality of projecting members 212 and the second plurality of projecting members 214 are perpendicular to the surface of the base 201. A certain number of projecting members is shown in FIG. 3 by way of example. The heat sink 200, as well as other heat sinks in accordance with embodiments of the present disclosure, may include any suitable number of projecting members of the first projecting members 212 and projecting members of the second plurality of projecting members 214.

As further shown in FIG. 3, the second plurality of projecting members 214 comprise two sets of projecting members, shown on the left and on the right, respectively, that are inwardly and upwardly angled relative to one another, i.e., towards the central longitudinal axis A1. In FIG. 3, the fins in one set extend along the base 201 such that they are slanted inwardly and upwardly from the left side of the base 201, and the fins in another set extend along the base 201 such that they are slanted or tilted inwardly and upwardly from the right side of the base 201. It should be noted that the projecting members of the second portion 204 can be also considered to be extending outwardly and downwardly, away from a part of the central longitudinal axis A1 that extends through the second portion 204.

The second portion 204 of the surface of the base 201 comprises a third portion 206 and a fourth portion 208. A third plurality of projecting members 216 extend from, and along, the third portion 206 and a fourth plurality of projecting members 218 extend from, and along, the fourth portion 208, wherein the third plurality of projecting members 216 and the fourth plurality of projecting members 218 are inwardly and upwardly angled relative to one another.

As shown in FIG. 3, the third plurality of projecting members 216 of the third portion 206 and the fourth plurality of projecting members 218 of the fourth portion 208 extend along the surface of the second portion 204 such that a central channel 220 is formed along the central longitudinal axis A1. It should be noted that the central longitudinal axis A1 coincides with a longitudinal axis (not shown) of the base 201, and the central longitudinal axis A1 is shown to illustrate symmetry of the third plurality of projecting members 216 and the fourth plurality of projecting members 218 with respect to a center line of the base surface of the heat sink 200.

The central channel 220 extends between the third plurality of projecting members 216 and the fourth plurality of projecting members 218. The central channel 220 is free from projecting members and it may have a generally upside-down trapezoidal shape, i.e. an upside-down trapezoidal shape that may be an exact trapezoid or a trapezoid with some possible minor variations from an exact trapezoidal shape, e.g., concave sides of the trapezoid. The shape of the central channel 220 and portions formed from the projecting members by the channel may also vary due to manufacturing variations. The shape of the central channel 220 may differ in various implementations of the heat sink 200, though the general shape remains upside-down trapezoidal. A longitudinal axis of the central channel 220 (not shown) may coincide with the central longitudinal axis A1. The central channel 220 may have a width, at its widest part, i.e., at the top, of from about 1% to about 10% of a width of the base 201, wherein the width of the base 201 is measured along an axis perpendicular to the central longitudinal axis A1.

Furthermore, it should be appreciated that the topology of the second plurality of projecting members 214, comprising the third plurality of projecting members 216 and the fourth plurality of projecting members 218, may differ from that shown in FIG. 3. Furthermore, a size and a number of channels formed in the third plurality of projecting members 216 and the fourth plurality of projecting members 218 may vary. A number of the projecting members in the first plurality of projecting members 212 and in the second plurality of projecting members 214 may also vary, depending on a specific implementation of the heat sink 200 in accordance with embodiments of the present disclosure.

The first and section portions 202, 204 may have substantially the same length or height, as measured along the central longitudinal axis A1 of the base 201. For example, the first portion 202 may occupy about 50% of the base 201 and the second portion 204 may similarly occupy about 50% of the base 201, wherein the overall length of the first and second portions 202, 204 is considered to be 100%. As used herein, “about” means the number itself and plus or minus within 5% of the stated number. For instance, about 50% means 50 and/or any number within a range of from 47.5 to 52.5, inclusive. In some implementations, the first portion 202 may occupy about 60% of the base 201 and the second portion 204 may occupy about 40% of the base 201. In some implementations, the first portion 202 may occupy about 40% of the base 201 and the second portion 204 may occupy about 60% of the base 201. The lengths of the first and section portions 202, 204 may depend on specifics of equipment or device that uses the heat sink 200, properties and requirements of the surrounding environment, and other factors.

Furthermore, spacing between projecting members of the first plurality of projecting members 212 and projecting members of the second plurality of projecting members 214 may depend on a type of a device in which the heat sink 200 is used.

It should be appreciated that the heat sink 200 may have other components that are not shown here for the sake of clarity of representation. The heat sink 200 may be coupled to a radio unit such as an RRU, or any other device. The heat sink 200 may be used in massive Multiple Input Multiple Output (MIMO) systems.

The conventional heat sink, e.g., as shown in FIG. 2, is known to maximize cooling for the bulk heat (e.g., temperature of 100° C. or about 100° C., a temperature range of from 95° C. to 105° C., or other temperature ranges), e.g., generated by analog components such as, e.g., (high-density) power transistors. The conventional heat sink, however, may not assist in cooling of digital components, e.g., printed circuit board (PCB) components such as, e.g, Field-Programmable Gate Arrays (FPGAs) and application-specific integrated circuits (ASICs). The digital components may heat up to about 90° C. The first and second portions of the hybrid heat sink in accordance embodiments of the present disclosure, e.g., as shown in FIG. 3, serve to together maximize analog component performance while decreasing the impact on the digital components (by the analog components). For example, the decrease in temperature of the digital components may be achieved, such that the temperature is lowered by e.g. 5° C. resulting in absolute temperature of about 85° C. In this way, the impact of the analog components on the digital components is reduced, thereby the thermal performance of digital components is improved.

FIG. 4 illustrates schematically acoustic and thermal design progression for heat sinks. General wind from the side direction, relative to a heat sink, is also schematically shown in connection with panel C, though the depiction of the wind is applicable to the heat sinks shown in panels A and B as well. FIG. 4 shows a conventional heat sink (panel A), a heat sink having an alternative configuration (panel B); and a hybrid heat sink in accordance with embodiments of the present disclosure (panel C). In the example herein, the conventional heat sink may be for radios of prior art, FIG. 2, and the alternative configuration is referred to as other prior art radios. As shown in panel B of FIG. 4, the alternative configuration of the heat sink includes only fins angled relative to a longitudinal axis (not shown) of the heat sink, and longitudinal channels may be formed in the fins. Examples of a heat sink having the alternative configuration, or a similar configuration, are described in PCT/SE2018/050083, which is incorporated by reference herein in its entirety. The alternative configuration may help in wind-induced noise, but thermal performance may be negatively affected, i.e. decreased, due to discontinuities (fins divided into many small fins, therefore losing valuable fin area) in the fins configuration.

A heat sink having the conventional design, as shown in panel A of FIG. 4, generates wind-driven acoustic noise (distinct, annoying frequencies) when the wind blows from a side direction, due to the uniformity of the structure. This requires modifications to the heat sink that introduces non-uniformity, to induce chaotic wind motion, to damp the noise generation. An example of such a modification is the alternative configuration of the heat sink in panel B of FIG. 4. However, this configuration adds complexity in design and reduces the thermal performance as well.

The hybrid heat sink encompasses a combination of a standard configuration of fins (or a configuration close to the standard configuration) and angled fins, in accordance with embodiments of the present disclosure, as described herein. The hybrid heat sink structure has structural non-uniformity which allowing creating chaotic, unsteady wind motion, which damps possible acoustic noise throughout the heat sink. The heat sink as shown, e.g., in panel C of FIG. 4 (which is similar to the heat sink 200 of FIG. 3 but includes additional channels formed in the lower portion of the base) allows achieving both increase in thermal performance and reduction in the wind-induced acoustical noise. Moreover, the hybrid structure described herein does not require any alterations to the general fin geometry, which simplifies manufacturing of the heat sink.

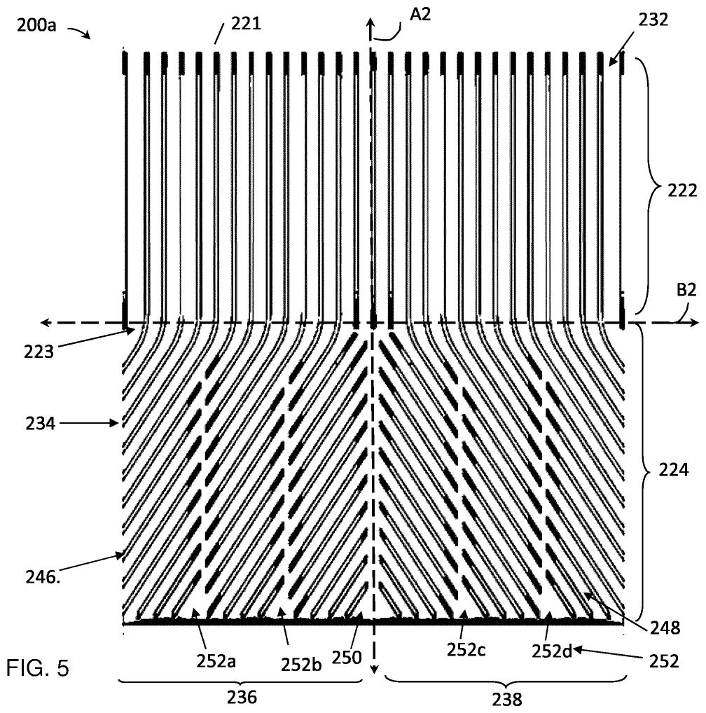

FIG. 5 illustrates a front view of a heat sink 200a in accordance with embodiments of the present disclosure. The heat sink 200a is an example of the heat sink 200 in FIG. 4 (panel C). The heat sink 200a includes channels extending through fins or projecting members of a lower portion, thereby separating some of the fins into smaller portions. The channels serve to breakdown the motion of the wind or other air movement in an enhanced fashion due to an additional level of non-uniformity in the geometry. The channels also allow decreasing weight of the heat sink.

As shown in FIG. 5, the heat sink 200a comprises a base plate or base 221 having a surface and a central longitudinal axis A2. The surface, which is not separately labeled herein since it coincides with the base 221 in the depiction of FIG. 5, comprises a first portion 222 and a second portion 224 disposed along the central longitudinal axis A2 such that the first portion 222 is above the second portion 224. The heat sink 200a also comprises a first plurality of projecting members or fins 232 and a second plurality of projecting members or fins 234.

The first plurality of projecting members 232 extend from the first portion 222 of the surface, wherein projecting members from the first plurality of projecting members 232 are elongated fully throughout the first portion along the surface parallel to one another and to the central longitudinal axis A2. The first plurality of projecting members 232 are substantially straight, i.e., straight or straight within an angle interval, such as within the interval of from about 1° to about 5°, which may be due to manufacturing variations, tolerances, and imprecisions. The first plurality of projecting members 232 are uniformly spaced along the first portion 222. As shown in FIG. 5, the first plurality of projecting members 232 extend along the surface in parallel rows, in a manner similar to the projecting members 103 of the conventional heat sink 100 of FIG. 2.

The second plurality of projecting members 234 extend from the second portion 224 of the surface. As shown in FIG. 5, at least parts or some projecting members from the second plurality of projecting members 234 are straightly elongated along the surface and arranged in an angled manner relative to the first plurality of projecting members 232. There may be a space, e.g., along a transverse axis B2, between the second plurality of projecting members 214 and the first plurality of projecting members 202. For example, a space or a channel may be formed along or approximately along (i.e., close to) the transverse axis B2. The space may be infinitesimally small. Alternatively, some or all of the projecting members from the first plurality of projecting members 222 may each extend further, in an angled configuration, along the second portion 224 of the base 221, so as to form projection members of the second plurality of projecting members 234. In FIG. 3, the transverse axis B2 is shown approximately where there is a border between the first plurality of projecting members 222 and the second plurality of projecting members 234, and that area is marked as 223.

Similarly to the heat sink 200 (FIG. 3), the second portion 224 of the surface of the base 201 comprises a third portion 236 and a fourth portion 238. A third plurality of projecting members 246 extend from, and along, the third portion 236. The fourth plurality of projecting members 248 extend from, and along, the fourth portion 238. The third plurality of projecting members 246 and the fourth plurality of projecting members 248 are upwardly and inwardly angled relative to one another, i.e., towards the central longitudinal axis A2 and towards one another, as viewed from the sides of the base 221.

As shown in FIG. 5, the third plurality of projecting members 246 of the third portion 236 and the fourth plurality of projecting members 248 of the fourth portion 238 extend along the surface of the second portion 224 such that a central channel 250 is formed along the central longitudinal axis A2. It should be noted that the central longitudinal axis A2 coincides with a longitudinal axis (not shown) of the base 221, and the central longitudinal axis A2 is shown to illustrate symmetry of the third plurality of projecting members 246 and the fourth plurality of projecting members 248 with respect to a center line of the base surface of the heat sink 200a. The central channel 250 has a generally upside-down trapezoidal shape. The exact shape of the central channel 250 may differ in various implementations of the heat sink 200a, though the general shape remains upside-down trapezoidal. The central channel 250 may have a width, at its widest part, i.e., at the top, of from about 1% to about 10% of a width of the base 221.

Spacing between the second plurality of projecting members 234 (i.e. between the rows of fins) may depend on spacing between the first plurality of projecting members 232. In embodiments, the spacing between projecting members of the second plurality of projecting members 234 is smaller than between corresponding projecting members of the first plurality of projecting members 232, wherein some of the projecting members of the second plurality of projecting members 234 are extensions of corresponding projecting members of the first plurality of projecting members 232.

In the heat sink 200a, as shown in FIG. 5, channels 252a, 252b, 252c, and 252d, collectively referred to as channels 252, are formed in the second plurality of projecting members 234. The channels 252a and 252b are formed in the third plurality of projecting members 246, and channels 252c and 252d are formed in the fourth plurality of projecting members 248. The channels 252 are formed such that some projecting members of the second plurality of projecting members 234 may not have the channels extending therethrough. In some implementations, all of the projecting members of the second plurality of projecting members 234 may have the channels extending therethrough. The channels may be formed through the entire surface of the projecting members, such that a bottom of the channels is formed by the surface of the base 221.

As shown in FIG. 5, the channels 252a and 252b in the third plurality of projecting members 246 are formed so that the channels 252a and 252b extend along a line that is slightly angled away, to the left in FIG. 5, relative to the central longitudinal axis A2. Similarly, the channels 252c and 252d are formed in the fourth plurality of projecting members 248 so that the channels 252c and 252d extend along a line that is slightly angled away, to the right in FIG. 5, relative to the central longitudinal axis A2. The channels 252a and 252b are formed symmetrically or approximately symmetrically relative to the channels 252c and 252d.

The configuration of the second plurality of projecting members or fins 234, and of the channels formed in the second plurality of projecting members allows efficient flow of air through the heat sink 200a.

It should be appreciated that the topology of the second plurality of projecting members 224, comprising the third plurality of projecting members 246 and the fourth plurality of projecting members 248, may differ from that shown in FIG. 5. Furthermore, a size and a number of channels formed in the third plurality of projecting members 246 and the fourth plurality of projecting members 248 may vary, as embodiments herein are not limited in this respect. A number of the projecting members in the first plurality of projecting members 232 and in the second plurality of projecting members 234 may also vary, depending on a specific implementation of a hybrid heat sink in accordance with embodiments of the present disclosure.

Hence, the heat sink 200 for a radio unit, herein provided, comprises:
the base 201 having the surface and the central longitudinal axis A1, the surface comprising the first portion 202 and the second portion 204 disposed along the central longitudinal axis A1 such that the first portion 202 is above the second portion 204. The heat sink comprises the first plurality of projecting members 212 extending from the first portion 202 of the surface, wherein the projecting members from the first plurality of projecting members 212 are elongated fully throughout the first portion 202 along the surface parallel to one another and to the central longitudinal axis A1, and wherein the first plurality of projecting members 212 are uniformly spaced along the first portion 202. The heat sink further comprises the second plurality of projecting members 214 extending from the second portion 204 of the surface, wherein at least parts or some projecting members of the second plurality of projecting members 214 are straightly elongated along the surface and arranged angled relative to the first plurality of projecting members 212.

The second portion 204 may have a plurality of channels 252,352 formed through at least some projecting members of the second plurality of projecting members 214.

The plurality of channels may extend along an axis forming an acute angle relative to the central longitudinal axis A1.

One or more channels of the plurality of channels 252 may be arranged in a trapezoidal shape wherein lower part is more narrow than upper part of the one or more channels.

The first portion 202 for cooling analog components may be arranged above the second portion 204 thereby reducing an impact of the analog components on digital components and thereby a thermal performance of the digital components is improved.

The second portion 204) of the surface may comprise the third portion 206 and the fourth portion 208, and the second plurality of projecting members 214 comprise the third plurality of projecting members 216 extending from the third portion 206 of the second surface and the fourth plurality of projecting members 218 extending from the fourth portion 208 of the second surface, wherein the third plurality of projecting members 216 and the fourth plurality of projecting members 218 are inwardly and upwardly angled relative to one another.

The plurality of channels 252 may comprise the central channel extending between the third plurality of projecting members and the fourth plurality of projecting members. The central channel may have an axis coinciding with the central longitudinal axis.

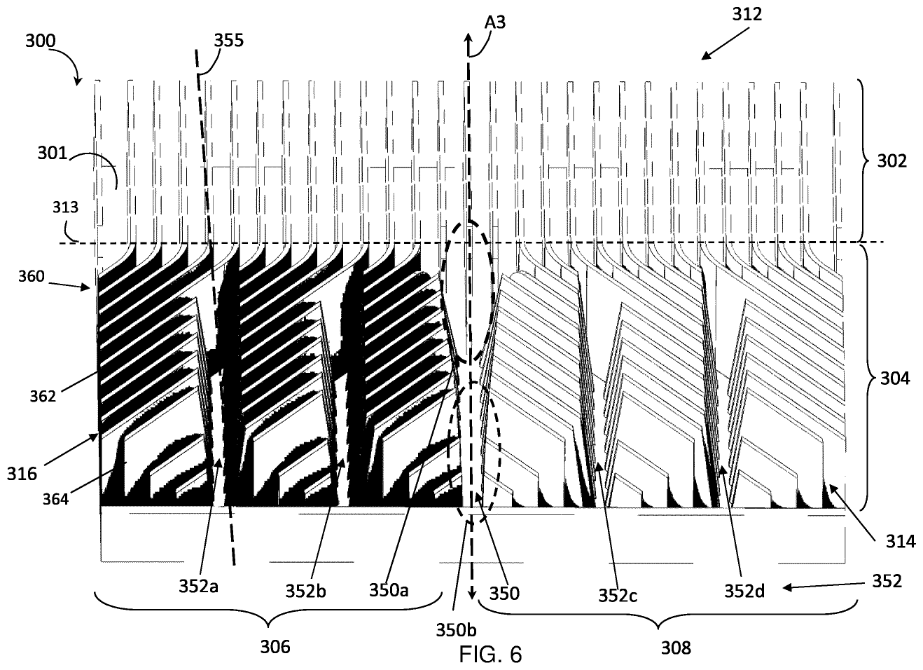

FIG. 6 illustrates a perspective side view of a heat sink 300 in accordance with embodiments of the present disclosure. The heat sink 300 is an example of the heat sink 200 of FIG. 3 and is therefore not described herein in detail. As shown in FIG. 6, the hybrid heat sink 300 has a base 301 comprising a surface having a first, top portion 302 and a second, lower or bottom portion 304. A first plurality of projecting members 312, having a configuration close to a conventional heat sink, extend from the first portion 302. A second plurality of projecting members 314 extend from the second portion 304, and channels 350 and 352 are formed in the projecting members 314. As shown in FIG. 6, surfaces the first plurality of projecting members 232 and the second plurality of projecting members 234 may be perpendicular to the surface of the base 221.

A boundary between the first plurality of projecting members 312 and the second plurality of projecting members 314 is shown by a line 313, though it should be appreciated that the change in the shape of a projecting member, from the first to the second portion, may be continuous. In other words, a straight (in the first portion) projecting member may gradually angle at an end side of the first portion wherein the projecting member begins being a part of the second portion.

The channel 350 is a central channel between projection members of a third portion 306 and projection members of a fourth portion 308 of the second portion 304. The central channel 305 may be symmetrical relative to a central longitudinal axis A3 of the base 301. The channels 352 comprise channels 352a, 352b, 352c, and 352d, with channels 352a and 352b formed in (third) projecting members of the third portion 306, and channels 352c and 352d formed in (fourth) projecting members of the fourth portion 308. It should be appreciated that five channels, including the central channel 350, are shown in FIG. 6 by way of example only, as any suitable number, e.g., fewer than 5 or greater than 5, of channels or cuts may be formed through the fins of the second portion 304.

As shown in FIG. 6, some of the projecting members of the third portion 306, having the central channel 350 extending therethrough, have corresponding, symmetrically disposed projecting members of the fourth portion 308, also having the central channel 350 extending therethrough.

As shown in FIG. 6, the central channel 350, extending between the projecting members of the third portion 306 and the projecting members of the fourth portion 308, may have a generally upside-down trapezoidal shape where the sides of the channel are concave such that an upper portion 350a of the channel 350 has a shape as shown in the example of FIG. 8A, and a lower portion 350b of the channel 350 has a shape as shown in the example of FIG. 8B. An example of a shape of each of the channels 352, which may have the same or approximately the same shape and size, is shown in FIG. 8C. Thus, one or more channels of a plurality of channels 252, 352 may be arranged in a trapezoidal shape wherein lower part is more narrow than upper part of the one or more channels. A length of the channels 352, as measured along the central longitudinal axis A3 of the base 301, may be from about 5 mm to about 200 mm, or from about 5 mm to about 100 mm, or about 70 mm. It should be noted that the shapes of the channels 350a, 350b, and 352 in FIGS. 8A, B, and C, respectively, are shown approximately in the same scale, for comparison.

In the example of FIG. 6, the channels 350 and 352 are formed in the projecting members of the second portion 304 such that edges of portions of the projecting members forming the channels are straight. However, it should be appreciated that the edges may be rounded or they may have other shapes.

As shown in FIG. 6, some of the projecting members do not have a channel formed therethrough. Thus, the five projecting members at the top left corner of the third portion 306, collectively marked with a numerical reference 360, are free from a channel. The projecting member 362 has the channel 352a extending therethrough, wherein the top, widest, part of the channel 352a is formed in the projecting member 362.

As further shown in FIG. 6, the channels 350 may be configured such that they extend at an acute angle relative to the central longitudinal axis A3 of the base 301. For example, as shown for the channel 352a, a longitudinal axis 355 of the channel 352a extends at an acute angle relative to the central longitudinal axis A3.

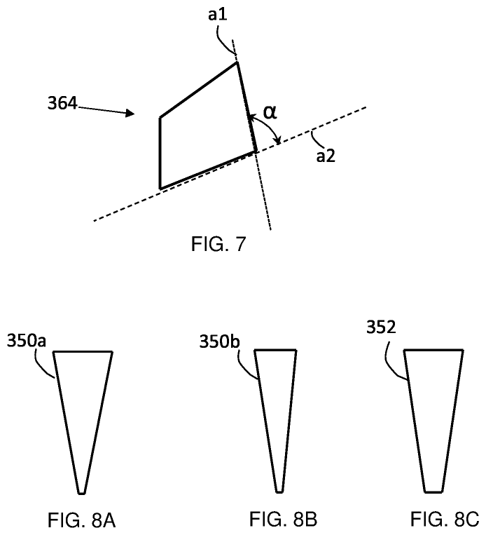

The channel 352a may be formed through at least some of the projecting members from the projecting members 316 such that resulting portions of the projecting members have a generally trapezoidal shape. Some of the projecting members may be divided into two or three (or other numbers, depending on an implementation) portions due to the channels formed therethrough. The side edges of the resulting portions may be slanted as shown in FIG. 6. As shown in FIG. 7, by way of example, for a portion of a fin or a projecting member 364 (also shown in FIG. 6), a certain angle α is formed between an axis a1 passing through a (right) side of the projecting member 364 and an axis a2 passing through a bottom edge of the projecting member 364 that is disposed on the surface of the base 301. The angle α may range from about 10° to about 60°. In some embodiments, the angle α may be about 33°, though it should be appreciated that the angle α may have other values.

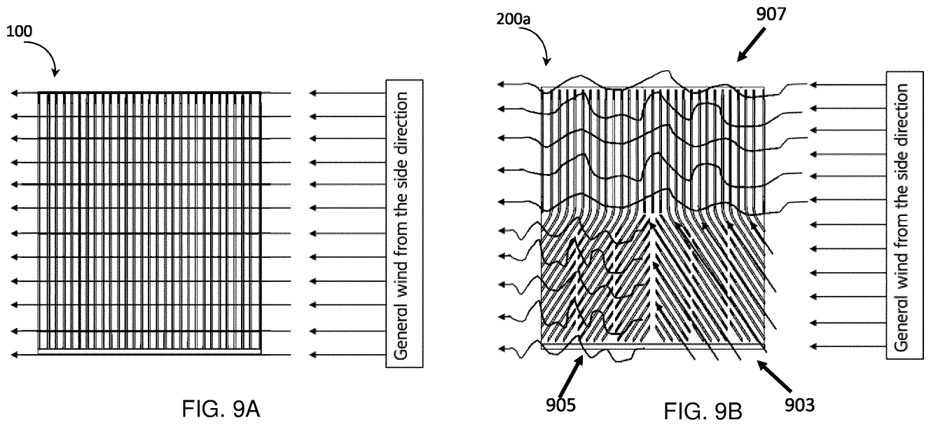

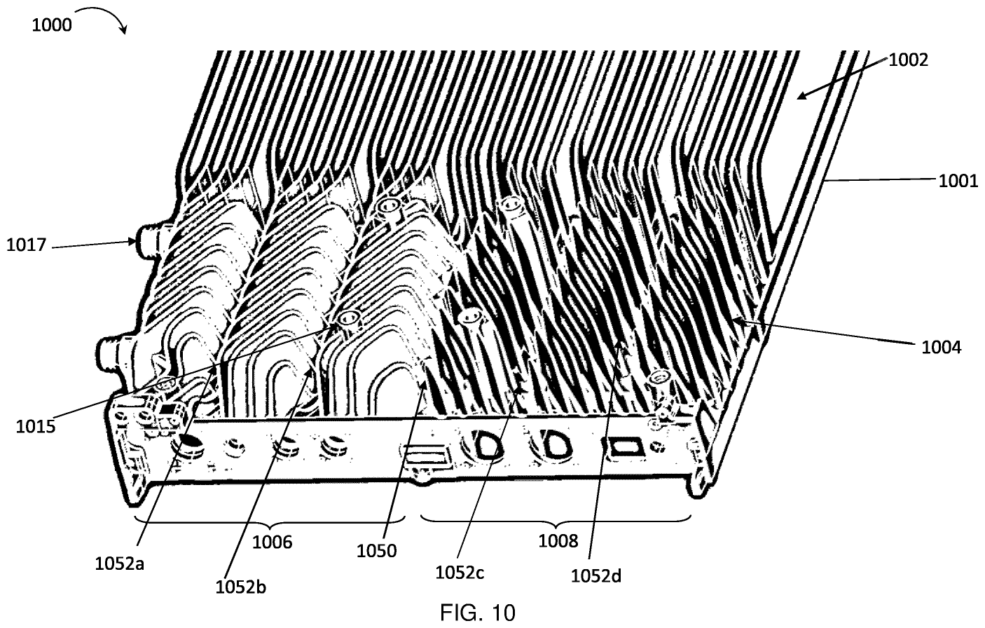

As discussed above, the heat sink 200 in accordance with embodiments of the present disclosure introduces structural non-uniformity and thereby chaotic, unsteady wind motion, which damps possible acoustic noise throughout the heat sink. The efficiency of the reduction of the acoustic noise may be improved in the heat sink having channels formed in a lower portion thereof, as shown, e.g., in FIGS. 4 (panel C), 5 and 6. FIGS. 9A and 9B schematically illustrate passage of wind through a conventional heat sink (FIG. 9A), and passage of wind through a hybrid heat sink in accordance with embodiments of the present disclosure (FIG. 9B). FIGS. 9A and 9B illustrate general wind from the side direction and show the bulk flow of air over the respective heat sink, indicating the relative flow structures. As shown in FIG. 9A for the conventional heat sink, shown by way of example as heat sink 100 (shown in FIG. 2), the wind may pass through the heat sink 100 essentially without a change in its direction.

In contrast, as shown in FIG. 9B for the heat sink 200, shown by way of example as heat sink 200a (shown in FIG. 5), the direction of the wind (903) entering the heat sink 200a through the side openings (created due to channels formed through projecting members of a lower portion of the heat sink 200a), is changed as the wind/air passes through the channels, as shown by arrows 905. The resulting chaotic, unsteady wind motion reduces acoustic noise that may be generated in the heat sink 200a. The heat sink 200a thus has a robust flow path definition by having additional flow paths on side inlets of the heat sink 200a, which reduce effects of possible flow obstruction. In addition, side access inlets for the heat sink 200a allow for enhanced cooling from outdoor wind fluctuations or other air movements. Due to the specific structure of the heat sink 200a, the direction of the wind entering the heat sink 200a through the side of the heat sink 200a also changes (907) to some degree in an upper portion of the heat sink 200a. In this way, both heat transfer capacity and noise reduction ability of the heat sink are improved.

FIG. 10 shows another example of the heat sink 200 as a heat sink 1000 having a base 1001 and a first and second portions 1002, 1004 on a surface of the base 1001, in accordance with embodiments of the present disclosure. The heat sink 1000 is similar to heat sink 200a (FIG. 5) and heat sink 300 (FIG. 6), but channels extend through projecting members of the second portion 1004 such that edges of portions of the projecting members are rounded. In this example, the second portion 1004 comprises third and fourth portions 1006, 1008, and channels 1050 (a central channel), 1052a, 1052bm 1052c, and 1052d extend through at least some of the projecting members of the third and fourth portions 1006, 1008.

It should be appreciated that the heat sink 1000, as well as other heat sinks described herein, have other components that may not be shown. Thus, FIG. 10 additionally shows that the heat sink 1000 includes mounting ports, such as front mounting port 1015, a side mounting port 1017, and other ports (not labelled), for attaching or mounting the heat sink 1000 to an object such as a radio unit, e.g., an RRU, or another device or equipment in which heat is generated by its electronic components. The object may be positioned in any outdoor or indoor environment.

It should be appreciated that, in embodiments herein, a height of projecting members may be the same throughout the heat sink 200. Furthermore, due to factors such as, e.g., manufacturing constraints, some of the projecting members may have different heights which does not affect the thermal and noise-reducing efficiency of the heat sink.

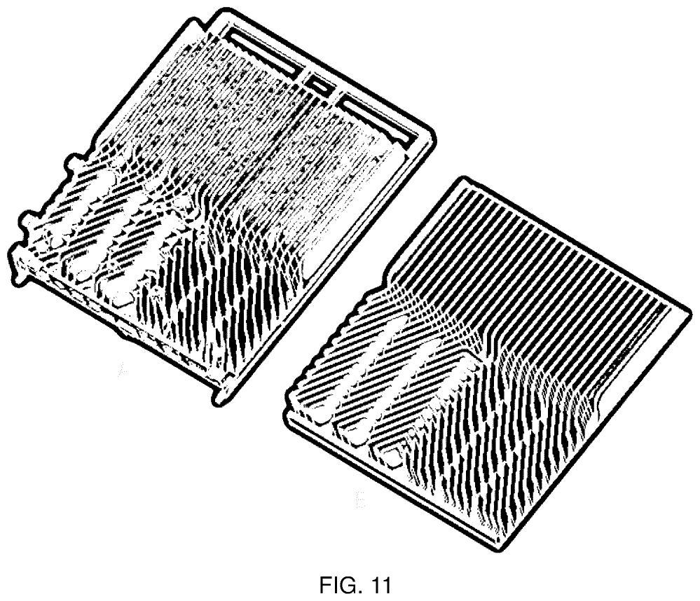

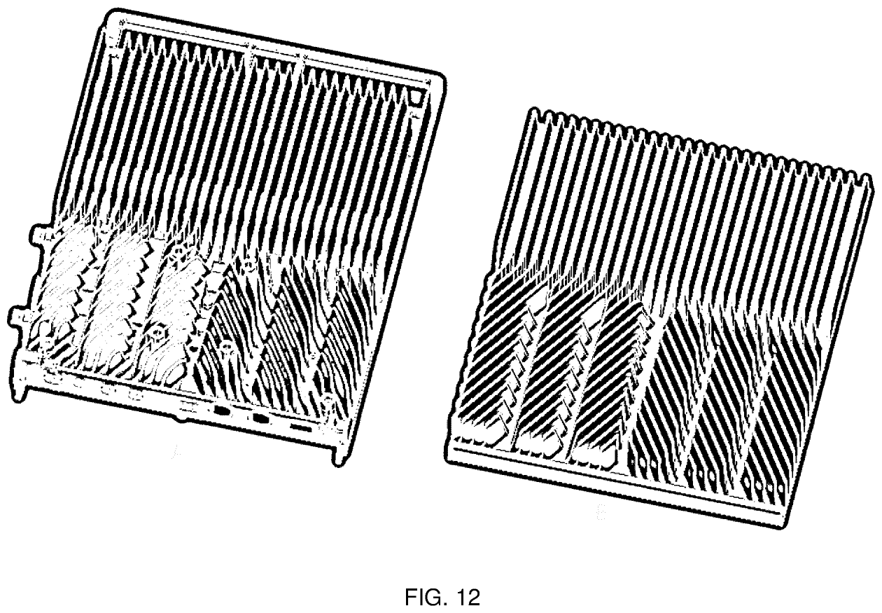

FIG. 11 shows two examples of heat sinks in accordance with embodiments herein, wherein the heat sink on the left (panel A) is similar to heat sink 1000 of FIG. 10 and the heat sink on the right (panel B) is similar to heat sink 300 of FIG. 6. FIG. 12 shows other perspective views of the heat sinks of FIG. 11. The heat sink on the left (panel A) is similar to heat sink 1000 of FIG. 10 and the heat sink on the right (panel B) is similar to heat sink 300 of FIG. 6.

Example Embodiments are summarized below:

A1. A heat sink comprising:
a base having a surface and a central longitudinal axis, the surface comprising first and second portions disposed along the central longitudinal axis such that the first portion is above the second portion;
a first plurality of projecting members extending from the first portion of the surface, wherein projecting members from the first plurality of projecting members are elongated along the surface parallel to one another and to the central longitudinal axis, and wherein the first plurality of projecting members and uniformly spaced along the first portion; and
a second plurality of projecting members extending from the second portion of the surface, wherein projecting members from the second plurality of projecting members are elongated along the surface and angled relative to the first plurality of projecting members.

A2. The heat sink of embodiment A1, wherein:
the second portion of the surface comprises third and fourth portions, and
the second plurality of projecting members comprise a third plurality of projecting members extending from the third portion of the second surface and a fourth plurality of projecting members extending from the fourth portion of the second surface, wherein the third plurality of projecting members and the fourth plurality of projecting members are inwardly and upwardly angled relative to one another.

A3. The heat sink of embodiment A2, wherein:
the second portion has a plurality of channels formed through at least some projecting members of the second plurality of projecting members.

A4. The heat sink of embodiment A3, wherein the plurality of channels extend along an axis forming an acute angle relative to the central longitudinal axis.

A5. The heat sink of embodiment A3 or embodiment A4, wherein the plurality of channels comprise a central channel extending between the third plurality of projecting members and the fourth plurality of projecting members.

A6. The heat sink of embodiment A5, wherein the central channel has an axis coinciding with the central longitudinal axis.

It will be appreciated that the foregoing description and the accompanying drawings represent non-limiting examples of the apparatus taught herein. As such, the apparatus and techniques taught herein are not limited by the foregoing description and accompanying drawings. Instead, the embodiments herein are limited only by the following claims and their legal equivalents.

1-8. (canceled)

9. A heat sink for a radio unit, wherein the heat sink comprises:
a base having a surface and a central longitudinal axis, the surface comprising a first portion and a second portion disposed along the central longitudinal axis;
a first plurality of projecting members extending from the first portion of the surface and a second plurality of projecting members extending from the second portion of the surface, disposed with a transverse axis boundary between the first and second plurality of projecting members, and
wherein projecting members from the first plurality of projecting members are elongated fully throughout the first portion along the surface parallel to one another and to the central longitudinal axis, and wherein the first plurality of projecting members are uniformly spaced along the first portion; and
wherein at least parts or some projecting members of the second plurality of projecting members are straightly elongated along the surface and arranged angled relative to the first plurality of projecting members, and wherein the second portion has a plurality of channels that divide the second plurality of projecting members into portions.

10. The heat sink of claim 9, wherein the channels are formed through cuts in at least some projecting members of the second plurality of projecting members.

11. The heat sink of claim 10, wherein the plurality of channels extend along an axis forming an acute angle relative to the central longitudinal axis.

12. The heat sink of claim 10, wherein one or more channels of the plurality of channels are arranged in a trapezoidal shape such that a lower part is more narrow than an upper part of the one or more channels.

13. The heat sink of claim 9, wherein the first portion for cooling analog components is arranged on a first side of a part of the transverse axis boundary and the second portion is arranged on a second side of the transverse axis boundary.

14. The heat sink of claim 9, wherein:
the second portion of the surface comprises a third portion and a fourth portion, and
the second plurality of projecting members comprise a third plurality of projecting members extending from the third portion of the second surface and a fourth plurality of projecting members extending from the fourth portion of the second surface, wherein the third plurality of projecting members and the fourth plurality of projecting members are inwardly and upwardly angled relative to one another.

15. The heat sink of claim 14, wherein the plurality of channels comprise a central channel extending between the third plurality of projecting members and the fourth plurality of projecting members.

16. The heat sink of claim 15, wherein the central channel has an axis coinciding with the central longitudinal axis.
